(19) United States
(12) Patent Application Publication
(10) Pub. No.: US 2016/0061872 A1
(43) Pub. Date: Mar. 3, 2016

(54) NON-DESTRUCTIVE SHORT CIRCUIT TESTING FOR ELECTRICALLY OPERATED CIRCUIT BREAKERS

(71) Applicant: James J. Kinsella, Brentwood, TN (US)

(72) Inventor: James J. Kinsella, Brentwood, TN (US)

(21) Appl. No.: 14/473,383

(22) Filed: Aug. 29, 2014

(51) Int. Cl. G01R 31/02; G01R 19/155; G01R 31/327

(52) U.S. Cl. CPC G01R 31/025; G01R 31/3277; G01R 19/155

(57) ABSTRACT

A testing assembly includes a power supply and at least one circuit phase corresponding to a circuit phase of a motor branch circuit assembly. The circuit phase includes a current detector, a transistor, and an isolating unit. The testing assembly also includes a switch selecting between a RUN mode and a TEST mode. The testing assembly is connected to the motor branch circuit assembly. Prior to placing the motor branch circuit assembly into operation, the testing assembly can provide low voltage testing on the circuit phases of the motor branch circuit assembly. The testing assembly can check for ground faults and line-to-line faults in the motor branch circuit assembly when placed into the Test mode. In this manner, faults destructive to the motor branch circuit assembly can be avoided and corrected.

### TECHNICAL FIELD

The present disclosure is related in general to electrical motor control and switchgear for the control and distribution of electrical energy and more particularly to non-destructive short circuit testing for electrically operated circuit breakers.

### BACKGROUND

The electric motor is at the core of most industrial processes. They are controlled and protected in the motor branch circuit by a combination of circuit breakers and contactors with a protective relay. The technology for motor branch circuits has remained virtually unchanged for the last 50 years.

An example of motor control using conventional circuit breakers and contactors can be found in Motor Control Centers (MCCs). These MCCs comprise columns of starters often 6 high in individually isolated units called ‘buckets’. The size of low kW starters is dominated by the conventional circuit breaker used for isolation and short circuit protection. Such conventional circuit breakers are expensive and too slow to provide damage free protection, particularly for what is termed International Electrotechnical Commission (IEC) control. Conventional circuit breakers also generate heat and their construction complicates electrical interconnects particularly on high kW ratings. The emphasis is on the ability to withstand fault currents rather than minimize damage.

Circuit breakers are typically mechanically operated and interlocked devices. They are energized with the expectancy of circuit integrity. If there are concerns about possible faults, these concerns are handled manually.

### BRIEF DESCRIPTION OF DRAWINGS

For a more complete understanding of the present disclosure, reference is made to the following description, taken in conjunction with the accompanying drawings, wherein like reference numerals represent like parts, in which:

FIG. 1 illustrates a motor branch circuit assembly;

FIG. 2 illustrates an addition of a low voltage testing assembly;

FIG. 3 illustrates a physical arrangement of the low voltage testing assembly.

### DETAILED DESCRIPTION

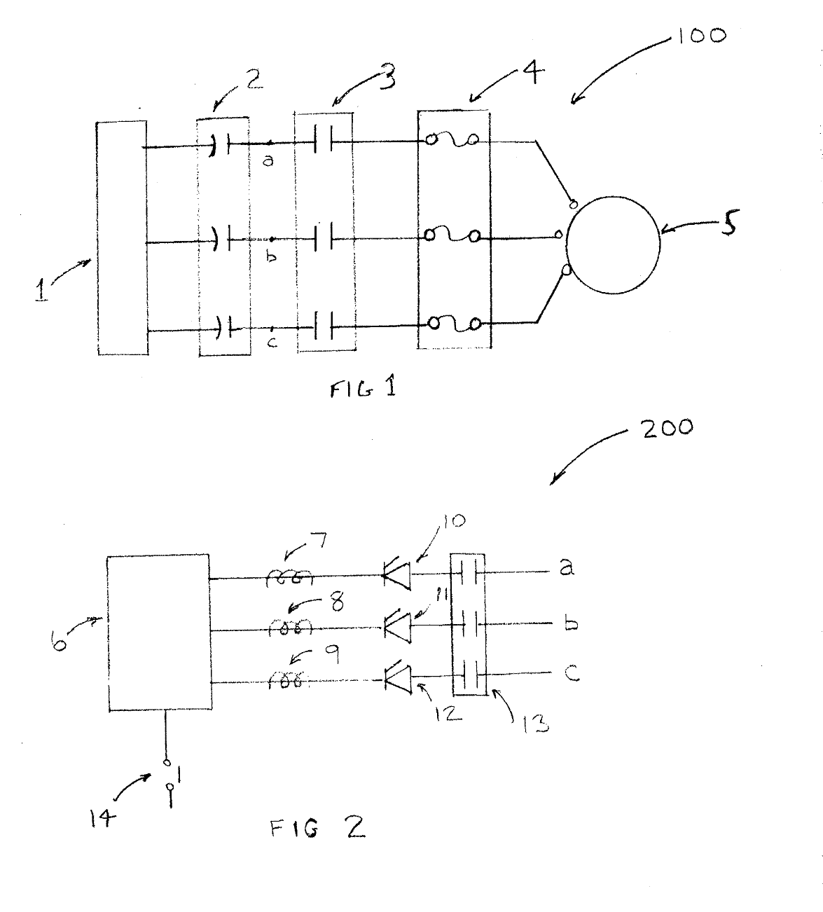

FIG. 1 illustrates a motor branch circuit assembly 100. Assembly 100 includes a motor 1, a circuit breaker 2, a contactor 3, and an overload relay 4. Line voltage is provided by a supply voltage 5. Assembly 100 also includes testing points a, b, and c for connecting a testing means thereto.

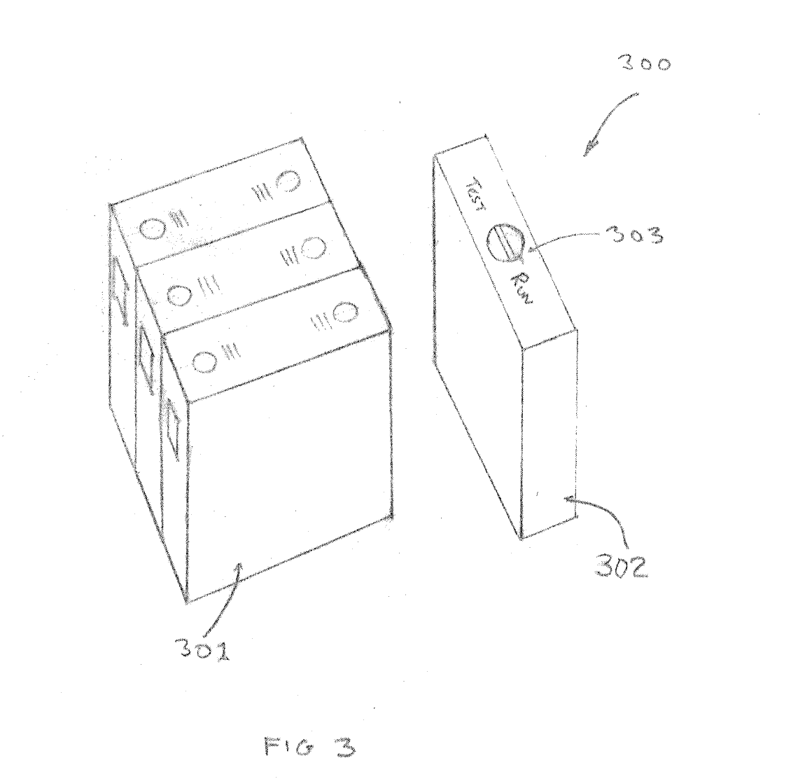

FIG. 2 illustrates a low voltage testing assembly 200. Testing assembly 200 includes a power supply 6, current detectors 7, 8 and 9, transistors 10, 11 and 12, and an isolating unit 13. Testing assembly 200 also includes a switch 14 selecting between a RUN mode and a TEST mode. Testing assembly 200 is connected to motor branch circuit assembly 100 at testing points a, b, and c of FIG. 1. Testing assembly 200 provides low voltage testing of electrical branch circuits prior to being placed into service.

FIG. 3 illustrates a physical configuration 300 for the assemblies. Physical configuration 300 includes a circuit breaker 301 and a low voltage testing assembly 302. On the front of low voltage testing assembly 302 is a TEST/RUN switch 303.

The basic idea is to allow for the sequential switching of low voltages to each phase in turn and then across each pair of phases in turn to test for faults prior to energizing the complete motor branch circuit assembly 100.

In the RUN mode, the motor branch circuit assembly 100 operates normally.

In the TEST mode, low voltage is applied through testing assembly 200 to check for any resultant current flows. The low voltage may be 24 volts DC. In this TEST mode, circuit breaker 2 is open and contactors 3 are closed. Two different tests may be performed while in the TEST mode.

The first test is for ground faults. Isolating unit 13 is closed. Isolating unit 13 may be an electrical switch, an electrical relay, or a mechanical means such as a connector or plug. Isolation unit 13 may be operated manually or automatically by a hard contact relay. Transistors 10, 11 and 12 (operating in a current limiting mode) are turned on sequentially to apply a test voltage to each line phase in turn looking for any leakage current to ground. Leakage current flowing would indicate faulty insulation. Any current flow is detected by current detectors 7, 8, and 9. Isolation unit 13 is rated with respect to line voltage. Sequential operation is controlled by power supply 6.

The second test is for line to line faults. In this mode, current flow is expected as the motor windings are in circuit. Thus, the line to line test is to check for short circuit currents that will be abnormal. Transistors are closed sequentially in pairs, 10-11, 11-12, and 12-10 to connect each single phase load circuit to inspect for abnormal current flow. Sequential operation is controlled by power supply 6.

In operation there may be long motor connections and/or internal motor or cable insulation degradation such that low voltage does not show a fault. For example, these may be arcing faults. Thus, the final step is to have the motor contactor closed with the circuit breaker open. Each pole of the circuit breaker is then closed sequentially for a short period of time so as to apply single phase voltage to motor 1 to ensure that the dielectric stress to ground shows no fault. When 3 pole circuit breakers are used, the circuit breaker is closed for a short period of time to test dielectric.

Other embodiments include making the testing automatic thus allowing testing to be carried out each time the equipment is put into service or at pre-planned intervals.

Testing assembly 200 can use 3 single pole electrically operated switches with or without transistors.

Low voltage testing assembly 200 can be built into the power supply for the circuit breaker 2 and be an integral assembly with it or remote from it. Also both power supply and testing means can be integrated into the circuit breaker assembly 301. In the case of the circuit breaker having independently operated poles, each pole of the circuit breaker or branch circuit protector may be sequentially closed to apply full voltage dielectric tests to each phase to test for ground faults.

For applications using power transistors, for example inverters, additional test points may be on the load side of the inverter. Non-destructive test voltages may be applied to the load side of the inverters to test for motor or cabling faults.

Although the present disclosure has been described in detail with reference to particular embodiments, it should be understood that various other changes, substitutions, variations, alterations, and modifications may be ascertained by those skilled in the art and it is intended that the present disclosure encompass all such changes, substitutions, variations, alterations, and modifications as falling within the spirit and scope of the appended claims. Moreover, the present disclosure is not intended to be limited in any way by any statement in the specification that is not otherwise reflected in the appended claims.

What is claimed is:

1. An apparatus for detecting faults in a motor branch circuit assembly, comprising:
a power supply;
at least one line phase corresponding to a line phase of the motor branch circuit assembly, each line phase including:
a current detector coupled to the power supply;
a transistor coupled to the current detector;
an isolating unit coupled to the transistor and the motor branch circuit assembly;
a switch coupled to the power supply and operable to place the apparatus in a test mode, the current detector operable to detect a presence of a current in the test mode when the isolation unit is closed, detection of the presence of the current indicating a ground fault in the corresponding line phase of the motor branch circuit assembly.

2. The apparatus of claim 1, wherein the power supply provides a low voltage to the line phase under test.

3. The apparatus of claim 2, wherein the low voltage is 24 volts DC.

4. The apparatus of claim 1, wherein the transistor operates in a current limiting mode.

5. The apparatus of claim 1, wherein the apparatus includes three line phases corresponding to three respective line phases of the motor branch circuit assembly, the apparatus operable to sequentially detect for the presence of the current indicating a ground fault for each line phase of the motor branch circuit assembly.

6. The apparatus of claim 5, wherein sequential operation control is integral with the power supply.

7. The apparatus of claim 5, wherein the apparatus is operable to sequentially close the transistors on the first and second line phases, the first and third cline phases, and the second and third line phases, detection of the presence of abnormal currents on the connected line phases when the corresponding transistors are closed indicating a line-to-line fault in the motor branch circuit assembly.

8. The apparatus of claim 7, wherein sequential operation controls are integral with the power supply.

9. The apparatus of claim 7, wherein sequential operation controls are integral with the motor branch circuit breaker assembly.

10. The apparatus of claim 1, wherein the isolating unit isolates the line phase from the line voltage of the motor branch circuit assembly.

11. A method for detecting faults in a motor branch circuit assembly, comprising:
placing the motor branch circuit assembly into a test mode;
detect a presence of a current in a line phase of the motor branch circuit assembly;
identifying a ground fault in the line phase of the motor branch circuit assembly in response to detection of the current.

12. The method of claim 11, further comprising:
providing a test voltage to the line phase under test.

13. The method of claim 12, wherein the test voltage is 24 volts DC.

14. The method of claim 12, wherein the test voltage is any suitable value.

15. The method of claim 11, wherein the motor branch circuit assembly includes three line phases, the method further comprising:
sequentially detecting for the presence of the current indicating a ground fault for each line phase of the motor branch circuit assembly.

16. The method of claim 15, further comprising:
controlling sequential detection of abnormal currents through a power supply integral with the motor branch circuit assembly.

17. The method of claim 16, further comprising:
providing sequential operation control integral with the power supply.

18. The method of claim 15, further comprising:
sequentially apply a test voltage to a first and a second line phase, the first and a third line phase, and the second and the third line phases;
detecting the presence of abnormal currents in the connected line phases when the corresponding line phases are closed;
identifying line-to-line faults in the motor branch circuit assembly in response to the detection of the current.

19. The method of claim 18, further comprising:
controlling sequential closing of the line phases through a power supply.

20. The method of claim 19, wherein sequential controlling control is either integrated with or remote from the motor branch circuit assembly.

21. The method of claim 11, further comprising:
isolating the line phases from a line voltage to the motor branch circuit assembly to permit testing.

22. The method of claim 11, further comprising:
isolating the low voltage test from a line voltage in normal operation.
